(19) United States
(12) Patent Application Publication
(10) Pub. No.: US 2026/0181802 A1
(43) Pub. Date: Jun. 25, 2026

(54) ELECTRONIC DEVICE AND PRODUCTION METHOD

(71) Applicant: Lenovo (Beijing) Limited, Beijing (CN)

(72) Inventor: Hongyang YU, Beijing (CN)

(21) Appl. No.: 19/421,875

(22) Filed: Dec. 16, 2025

(30) Foreign Application Priority Data
Dec. 20, 2024 (CN) 202411896902.8

(51) Int. Cl. H05K 5/02; H05K 5/00

(52) U.S. Cl. CPC H05K 5/0243; H05K 5/0086

(57) ABSTRACT

An electronic device includes a housing including a target texture layer and a surface layer. In a thickness direction of the housing, a height of the target texture layer is different from a height of the surface layer. The target texture layer is obtained by stamping the surface layer, the target texture layer is irregular in shape, and the target texture layer presents a leather-like visual effect. The surface layer has a roughness achieved by processing the surface layer with a sandblasting process.

### CROSS-REFERENCE TO RELATED APPLICATION

This application claims priority to Chinese Patent Application No. 202411896902.8, filed on Dec. 20, 2024, the entire content of which is incorporated herein by reference.

### TECHNICAL FIELD

The present disclosure generally relates to the electronic device field and, more particularly, to an electronic device and a production method.

### BACKGROUND

As electronic devices become more sophisticated in appearance and more abundant in products, people have gradually developed aesthetic fatigue toward the uniformity of device surfaces.

### SUMMARY

In accordance with the disclosure, there is provided an electronic device including a housing including a target texture layer and a surface layer. In a thickness direction of the housing, a height of the target texture layer is different from a height of the surface layer. The target texture layer is obtained by stamping the surface layer, the target texture layer is irregular in shape, and the target texture layer presents a leather-like visual effect. The surface layer has a roughness achieved by processing the surface layer with a sandblasting process.

Also in accordance with the disclosure, there is provided a production method including stamping a surface layer of a housing to form a target texture layer on the housing, and processing the surface layer with a sandblasting process to achieve a roughness on the surface layer. In a thickness direction of the housing, a height of the target texture layer is different from a height of the surface layer, the target texture layer is irregular in shape, and the target texture layer presents a leather-like visual effect.

### BRIEF DESCRIPTION OF THE DRAWINGS

To more clearly illustrate the technical solutions in the embodiments of the present disclosure, the drawings used in the description of the embodiments will be briefly introduced below. Obviously, the drawings described below are merely some embodiments of the present disclosure. For those skilled in the art, other drawings can be obtained based on the present disclosure without creative effort.

FIG. 1 is a schematic diagram of an electronic device consistent with the present disclosure.

FIG. 2 is a schematic diagram of a housing consistent with the present disclosure.

FIG. 3 is showing a target texture layer consistent with the present disclosure.

FIG. 4 is a flowchart of a production method consistent with the present disclosure.

FIG. 5 is a flowchart of another production method consistent with the present disclosure.

FIG. 6 is a schematic structural diagram of a first mold, a second mold, and a third mold consistent with the present disclosure.

FIG. 7 is a flowchart of another production method consistent with the present disclosure.

FIG. 8 is a flowchart of another production method consistent with the present disclosure.

FIG. 9 is a flowchart of another production method consistent with the present disclosure.

FIG. 10 is a flowchart of producing a housing for an electronic device consistent with the present disclosure.

FIG. 11 is showing a housing in one form consistent with the present disclosure.

FIG. 12 is showing a housing in another form consistent with the present disclosure.

### REFERENCE NUMERALS

1—Housing; 11—Target texture layer; 12—Surface layer; 111—First part; 112—Second part.

### DETAILED DESCRIPTION OF THE EMBODIMENTS

Various aspects and features of the present disclosure are described herein with reference to the accompanying drawings.

It should be understood that various modifications may be made to the embodiments of the application herein. Therefore, the above description should not be taken as limiting, but merely as exemplification of the embodiments. Other modifications within the scope and spirit of the application will occur to persons of ordinary skill in the art.

The accompanying drawings, which are incorporated in and constitute a part of this specification, illustrate embodiments of the application and, together with a general description of the application given above, and the detailed description of the embodiments given below, serve to explain the principles of the application.

These and other characteristics of the application will become apparent from the following description of embodiments, given as non-limiting examples, with reference to the accompanying drawings.

It is also to be understood that, although the application has been described with reference to some specific examples, a person skilled in the art will certainly be able to achieve many other equivalent forms of the application, having the characteristics as set forth in the claims and hence all coming within the field of protection defined thereby.

The above and other aspects, features and advantages of the present disclosure will become more apparent in light of the following detailed description when taken in conjunction with the accompanying drawings.

Specific embodiments of the application will be described hereinafter with reference to the accompanying drawings. It is, however, to be understood that the embodiments so applied are merely examples of the application, which may be practiced in various ways. Well-known and/or repeated functions and constructions are not described in detail to avoid obscuring the application with unnecessary or redundant details. Therefore, specific structural and functional details disclosed herein are not intended to be limiting, but merely as a basis for the claims and as a representative basis for teaching one skilled in the art to variously employ the present disclosure in virtually any appropriately detailed structure.

The specification may use the word “in one embodiment,” “in another embodiment,” “in yet another embodiment,” or “in other embodiments,” which may each refer to one or more of the same or different embodiments in accordance with the application.

For the convenience of understanding the present disclosure, an electronic device provided by the present disclosure will be described in detail. In the embodiments described below, a notebook computer is taken as an example of the electronic device, and those skilled in the art should know that the electronic device of the present disclosure may also be other devices such as a display, a tablet computer, a mobile phone, etc.

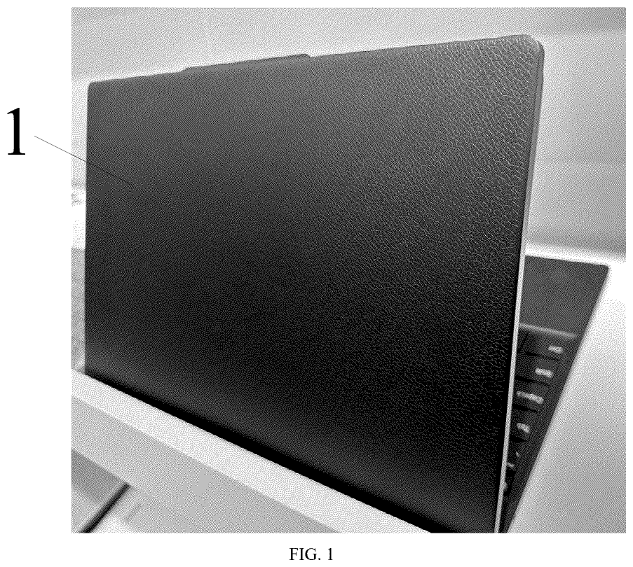

FIG. 1 shows a schematic diagram of an electronic device. As shown in FIG. 1, the electronic device includes a housing 1. The electronic device may also include a body, buttons, etc.

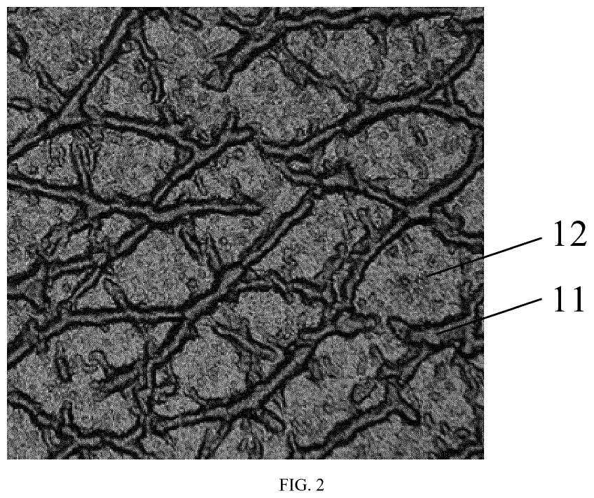

In some embodiments, referring to the schematic diagram of the housing shown in FIG. 2, the housing 1 includes a target texture layer 11 and a surface layer 12. The housing 1 can be made from sheet metal such as aluminum alloy, magnesium-aluminum alloy, or titanium alloy, and formed to a certain size. The surface layer 12 is a planar layer of the housing, and processes such as stamping and polishing can be performed on this planar layer. The target texture layer 11 is obtained by stamping the surface layer 12 of the housing 1, that is, stamping the surface layer 12 to obtain a target texture layer 11 different from the surface layer 12. The target texture layer 11 can be irregular in shape to present a leather-like visual effect, that is, the user visually perceives it as a leather product rather than a metal product. Furthermore, the irregular shape of the target texture layer 11 can enhance the leather-like visual effect. Compared with the uniform-surface visual effect of current electronic devices, the target texture layer 11 of the housing 1 effectively enriches the visual effect of the housing.

Leather surfaces have characteristics of irregularity, such as wrinkles and texture variations. In the present disclosure, the target texture layer 11 is irregular in shape, meaning the texture distribution of the target texture layer 11 is not predictable. Its texture distribution is a non-man-controlled irregular pattern, and the irregular shape can present a simulated, naturally generated leather-like visual effect, as shown in FIGS. 1, 11, and 12. Furthermore, when the user views the housing, it is as if they are viewing tanned animal skin; this leather-like visual effect gives the housing 1 a simulation effect (imitating animal skin).

Leather surfaces are typically not completely smooth but have a certain texture and roughness. In one embodiment, the surface layer 12 of the housing 1 in the present disclosure may have a first roughness. The first roughness can be obtained by sandblasting the surface layer 12 with a first-size sandblasting process. The presence of the first roughness causes light to scatter and reflect at multiple angles on the surface. This scattering effect makes light randomly distributed on the surface, avoiding strong reflected light spots, making the surface layer 12 look more matte and natural, and making the housing 1 visually similar to genuine leather. By introducing a first roughness into the surface layer 12 through a sandblasting process, this natural light scattering effect can be effectively mimicked, thereby enhancing the leather-like visual effect of the housing 1.

In one embodiment, the target texture layer 11 and the surface layer 12 have different heights in the thickness direction of the housing 1, that is, the thickness of the target texture layer 11 is different from the thickness of the surface layer 12 on the housing 1. The combination of the surface layer 12 and the target texture layer 11 gives the housing 1 a leather-like visual effect, effectively enriching the visual effect of the housing 1. Compared to patching leather, the housing in the present disclosure does not require the addition of other materials, resulting in lower costs. At the same time, the housing avoids splicing problems caused by the combining different materials, thus ensuring the quality of the housing.

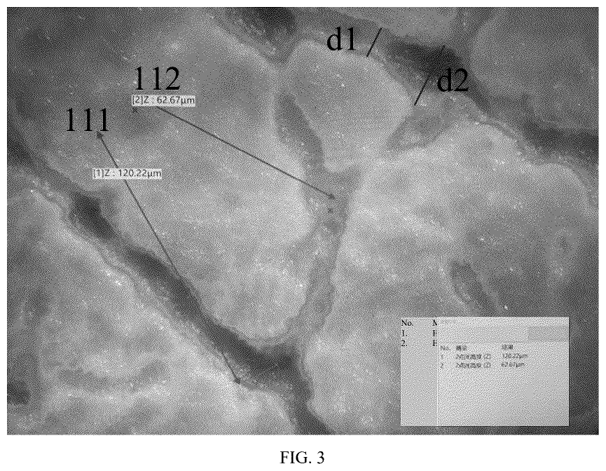

In some embodiments, the molds, forging actions, and/or stamping actions used during the stamping process may cause differences between different parts of the target texture layer 11. Taking FIG. 3 as an example, the target texture layer 11 includes a first part 111 and a second part 112. The height difference between the first part 111 and the surface layer 12 is a first value, which is the difference between the thickness of the first part 111 of the target texture layer 11 and the thickness of the surface layer 12. The height difference between the second part 112 and the surface layer 12 is a second value, which is the difference between the thickness of the second part 112 of the target texture layer 11 and the thickness of the surface layer 12. The first value and the second value are different. That is, the thickness of the first part 111 is different from the thickness of the second part 112, that is, the texture depth of the first part 111 is different from the texture depth of the second part 112. In one embodiment, both the first value and the second value are less than or equal to 40 μm, but the difference between the first value and the second value is less than or equal to 15 μm. For example, the first value is 39 μm, and the corresponding second value is 25 μm. As another example, the first value is 37 μm, and the corresponding second value is 24 μm. As another example, the first value is 34 μm, and the corresponding second value is 25 μm, etc. Furthermore, the first value and the second value are random and are not fixed. In the present disclosure, the difference between various parts of the target texture layer 11 makes the texture of the target texture layer 11 irregular, improving the natural visual effect of the target texture layer 11 and thus enhancing the leather-like visual effect presented by the target texture layer 11.

In some embodiments, referring to FIGS. 1-3, the width of the texture of each part of the target texture layer 11 can also be different. The width of the texture is the dimension value of the texture in the direction perpendicular to the extension direction of the texture. For example, d1 and d2 in FIG. 3 are the widths of the texture. The width of the texture is less than or equal to 170 μm. Of course, the width of the texture is also random and not fixed. In FIGS. 2 and 3, the width of the texture can be 0, and the width of the texture can also be 85 μm, 112 μm, or even 170 μm. In one embodiment, the width of at least a part of the texture of the target texture layer 11 can be set to be less than the first size, so that when the surface layer 12 is processed with a sandblasting process of the first size to obtain the first roughness, the iron sand used in the sandblasting process will not affect the texture of the target texture layer 11. Of course, the width of all textures can be set to be smaller than the first size to ensure, to a large extent, that the target texture layer 11 can present a leather-like visual effect after the sandblasting process. In one embodiment, the first size can be set to be greater than or equal to 90 mesh, such as 90 mesh, 100 mesh, etc. (“mesh” is a unit literally referring to the number of openings per inch, and in the context of sandblasting process, it is used to characterize the size of the particles by referring to the opening size of the screen that the particles can pass through; for example, an iron sandblasting process with 90 mesh can mean that the iron sand used in this process has a particle size fine enough to allow it to pass through a screen with 90 openings per inch), as long as it can prevent the iron sand from affecting the texture of the target texture layer 11. Correspondingly, the first roughness corresponds to the specification of the iron sand. For example, a surface parameter corresponding to the first roughness formed by iron sand of the first size is less than or equal to 1.8 μm. It should be understood that the roughness formed by iron sand of the same mesh number may also be different.

In another embodiment, the first size is in the range of 90 mesh to 100 mesh, that is, the surface layer 12 can be sandblasted with iron sand of a size in the range of 90 mesh to 100 mesh to obtain the first roughness. Correspondingly, the surface parameter, which can characterize the roughness of a surface layer, corresponding to the first roughness can be in the range of 1.4 μm to 1.8 μm. In the present disclosure, the surface parameter can be set as the arithmetic mean of the absolute values of the profile offset within a sampling length, it can also set to be a combination of this surface parameter and other parameters. The other parameters may include, for example, the sum of the average of the five largest profile peak heights and the average of the five largest profile valley depths within the sampling length, and the distance between the profile peak line and the profile valley line within the sampling length L.

In one embodiment, at least a part of the texture of the target texture layer 11 has a second roughness, obtained by sandblasting the surface layer 12 with a second-sized process. This second size is smaller than the first size, so that the iron sand of the second size can affect at least a part of the texture of the target texture layer 11, thus enabling at least a part of the texture of the target texture layer 11 to be sandblasted. The second size and the first size characterize the specification of the iron sand used in the sandblasting process. In one embodiment, the second size can also be set to be greater than or equal to 90 mesh. Since the iron sand of the second size can affect at least a part of the texture of the target texture layer 11, the second size can be set to be greater than or equal to 100 mesh, i.e., the second size can be set to 100 mesh, 110 mesh, etc. In one embodiment, the second size is set to be in the range of 100 mesh to 120 mesh to ensure a better leather-like visual effect presented by the target texture layer 11. Correspondingly, the second roughness corresponds to the second size of the iron sand, for example, the second roughness formed by iron sand of the second size is less than or equal to 1.5 μm.

In the present disclosure, by setting the width of at least a part of the texture of the target texture layer 11 to be less than the first size, or by having at least a part of the texture of the target texture layer 11 possess a second roughness, combined with a surface layer 12 possessing a first roughness, the leather-like visual effect presented by the target texture layer 11 is enhanced. Here, compared to a target texture layer 11 without a second roughness combined with a surface layer 12 possessing a first roughness, the combination of at least a part of the texture of the target texture layer 11 possessing a second roughness with a surface layer 12 possessing a first roughness makes the leather-like visual effect more natural.

In some embodiments, the target texture layer 11 obtained by stamping the surface layer 12 of the housing 1 may have different widths for different texture parts, but the width of each texture part can be set to less than or equal to 170 μm to avoid color differences between different texture parts. Each part of the target texture layer can be a texture of any length, and the lengths of different texture parts can vary.

In another embodiment, the target texture layer 11 obtained by stamping the surface layer 12 of the housing 1 may have different texture depths for the first part 111 and the second part 112, but both the texture depths of the first part 111 and the second part 112 can be set to be greater than or equal to 40 μm. That is, in the thickness direction of the housing 1, the height difference between the first part 111 and the surface layer 12 of the target texture layer 11, and the height difference between the second part 112 and the surface layer 12 of the target texture layer 11, can both be set to be greater than or equal to 40 μm, i.e., the height difference between the target texture layer 11 and the surface layer 12 can be set to be greater than or equal to 40 μm.

The electronic device housing of the present disclosure includes a target texture layer and a surface layer of different heights. The target texture layer is irregular in shape and exhibits a leather-like visual effect. The surface layer has a first roughness. The target texture layer and surface layer enable the electronic device housing to achieve a genuine leather-like visual effect, effectively enriching the visual appeal of the housing. Furthermore, it eliminates the need for additional materials such as genuine leather, resulting in lower costs. At the same time, it avoids splicing problems caused by combining different materials, ensuring the quality of the housing.

The present disclosure also provides a method which can be used to fabricate the above electronic device housing.

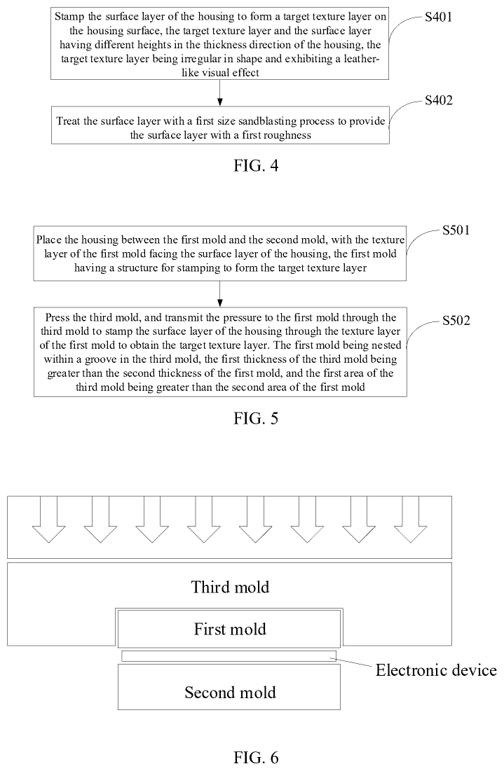

For example, FIG. 4 shows a flowchart of the production method provided by the present disclosure. The method includes the following.

At S401, the surface layer of the housing is stamped to form a target texture layer on the housing surface, the target texture layer and the surface layer having different heights in the thickness direction of the housing and the target texture layer being irregular in shape and exhibiting a leather-like visual effect.

At S402, the surface layer is treated with a first-size sandblasting process to realize a first roughness.

In one embodiment, after obtaining the housing of the electronic device, the surface layer of the housing is stamped to form a target texture layer on the housing surface. In some embodiments, the stamping pressure used to stamp the surface layer of the housing is in the range of 700 T to 900 T (“T” here means ton). In some embodiments of the present disclosure, the maximum stamping pressure is limited to 900 T, which can, to a certain extent, prevent the housing and/or the mold used during stamping from breaking under extreme pressure. Furthermore, the stamping temperature used during stamping the surface layer of the housing is greater than or equal to 300° C. Stamping the surface layer of the housing under the stamping pressure and the stamping temperature causes deformation in a part of the housing, that is, the target texture layer can be formed on the housing. For example, when the stamping pressure is 900 T, the corresponding stamping temperature is 300° C.; another example is when the stamping pressure is 800 T, the corresponding stamping temperature is 350° C., etc. Within permissible limits, i.e., a stamping pressure in the range of 700 T to 900 T and a stamping temperature greater than or equal to 300° C., a higher stamping pressure corresponds to a lower stamping temperature, resulting in a better target texture layer without damaging the housing.

The target texture layer is obtained by altering the shape of a part of the surface layer, thus the housing is a single part. Compared to housing made by attaching genuine leather to the surface, a single part housing avoids splicing problems caused by combining different materials, while ensuring housing quality.

Since the target texture layer is obtained by altering the shape of a part of the surface layer, the heights of the target texture layer and the surface layer differ in the thickness direction of the housing. In one embodiment, the height difference between the target texture layer and the surface layer is greater than or equal to 40 μm. Furthermore, the target texture layer is irregular in shape and exhibits a leather-like visual effect. Therefore, the combination of the target texture layer and the surface layer give the housing a genuine leather-like visual effect.

In some embodiments, after the surface layer of the housing is stamped, the surface layer is treated with a first-size sandblasting process so that the surface layer has a first roughness. The first roughness in the present disclosure can be the same as or similar to the first roughness in the previous embodiments.

In one embodiment, the first size is used to characterize the size of the iron sand used in the sandblasting process. The first size can be set to in the range of 100 mesh to 120 mesh, i.e., the surface layer is sandblasted using iron sand of size in the range of 100 mesh to 120 mesh. Correspondingly, a surface parameter formed on the surface layer can be in the range of 1.4 μm to 1.8 μm, and this surface parameter can be the arithmetic mean of the absolute values of the profile offset within a sampling length. A surface layer with this first roughness, combined with a target texture layer, can give the housing a genuine leather-like visual effect.

Furthermore, the surface layer is set to have a first roughness, combined with a target texture layer, can conceal appearance defects to a certain extent, thereby improving the yield rate of housing production.

For example, FIG. 5 shows a flowchart of another production method provided by the present disclosure. The method includes the following.

At S501, the housing is placed between the first mold and the second mold, with the texture layer of the first mold facing the surface layer of the housing, the first mold having a structure for stamping to form the target texture layer.

At S502, the third mold is pressed, and the pressure is transmitted to the first mold through the third mold to stamp the surface layer of the housing through the texture layer of the first mold, thus obtaining the target texture layer. The first mold is nested within a groove in the third mold. The first thickness of the third mold is greater than the second thickness of the first mold, and the first area of the third mold is greater than the second area of the first mold.

Considering that directly applying pressure to the mold during stamping can easily lead to mold breakage, and that if the mold with the texture layer breaks, a new mold needs to be fabricated according to the same texture layer, which is time-consuming and increases mold cost while also affecting stamping efficiency, the production method of this embodiment uses a combination of the first mold, the second mold, and the third mold for stamping.

In one embodiment, a schematic diagram of the structure of the first mold, the second mold, and the third mold is shown in FIG. 6, in which, the first mold, the second mold, and the third mold can be nested together to form the texture layer.

When the surface layer of the housing is stamped, the housing is first placed between the first mold and the second mold, with the texture layer of the first mold facing the surface layer of the housing. That is, under external pressure, the texture layer of the first mold and the surface layer of the housing can directly contact each other. The first mold includes a structure for stamping to form the target texture layer. When the first mold is subjected to external pressure, causing the texture layer to directly contact the surface layer of the housing, the structure included in the first mold can form the target texture layer on the housing.

Referring to FIG. 6, the first mold is nested within a groove provided at the third mold. When the surface layer of the housing is stamped, pressure can be applied to the third mold. The direction of this pressure is towards the housing. The pressure is transmitted to the first mold through the third mold, so that the surface layer of the housing is stamped through the texture layer of the first mold, thereby obtaining the target texture layer.

In the present disclosure, a combination of the first mold, the second mold, and the third mold is used to perform the stamping process. Transmitting pressure to the first mold through the third mold can, to some extent, prevent the first mold from breaking due to direct pressure. Furthermore, if the first mold breaks, the first mold needs to be remade with texture layer. In the present disclosure, the pressure is transmitted to the first mold through the third mold, so even if a break occurs, the breakage will occur on the third mold. Compared to remaking the first mold with texture layer, making the third mold can effectively reduce mold costs. In one embodiment, the third mold can be adapted to first molds of various sizes, meaning the third mold can be adapted to first molds smaller than its groove size. This improves the applicability and flexibility of the first, second, and third molds.

In some embodiments, the first thickness of the third mold is greater than the second thickness of the first mold, and the first area of the third mold is greater than the second area of the first mold. This effectively prevents the first mold from breaking during stamping. Taking a laptop computer as an example, the length and width of the electronic device's housing are 330×220 mm. Correspondingly, the length and width of the first mold are 460×370 mm, and the total thickness of the third mold and the first mold is greater than or equal to 70 mm. Specifically, the first thickness of the third mold is greater than or equal to 40 mm, and the second thickness of the first mold is greater than or equal to 30 mm. Of course, those skilled in the art should understand that when the electronic device is a monitor, tablet computer, mobile phone, etc., the length and width of the first mold can be adjusted accordingly.

In some embodiments, the texture layer of the first mold may include a structure for stamping to form the target texture layer. When the first mold is subject to pressure, the structure of the texture layer acts on the surface layer of the housing to form the target texture layer. In one embodiment, the structure can be a protrusion on the surface of the first mold, having a certain height compared to the surface of the first mold. The height of the structure can be set to in the range of 60 μm to 80 μm. The structure with this height allows the height difference between the formed target texture layer and the surface layer to be greater than or equal to 40 μm. In one embodiment, the structure has a certain width in a direction perpendicular to its extension direction, and the width of the structure can be set to be less than or equal to 170 μm. The structure with this width allows the texture width of the formed target texture layer to be less than or equal to 170 μm, thus giving the target texture layer a leather-like visual effect.

In some embodiments, the height of the structure is in the range of 60 μm to 80 μm, meaning that the heights of different parts of the structure can differ. Based on this, when the target texture layer is formed by stamping using this structure, the resulting target texture layer can include a first part and a second part, and the texture depth of the first part is different from the texture depth of the second part. Correspondingly, the height of the structure forming the first part is different from the height of the structure forming the second part.

Therefore, the height difference between the first part and the surface layer is a first value, and the height difference between the second part and the surface layer is a second value. The first value and the second value can be different.

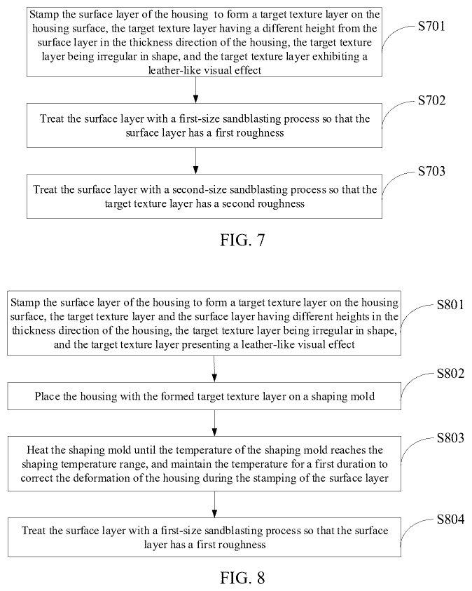

In some embodiments, after the surface layer is treated with a first-size sandblasting process, it can also be treated with a second-size sandblasting process. FIG. 7 is a flowchart of another production method provided by the present disclosure, and the method includes the following.

At S701, the surface layer of the housing is stamped to form a target texture layer on the housing surface, the target texture layer having a different height from the surface layer in the thickness direction of the housing, the target texture layer being irregular in shape, and the target texture layer exhibiting a leather-like visual effect.

At S702, the surface layer is treated with a first-size sandblasting process so that the surface layer has a first roughness.

At S703, the surface layer is treated with a second-size sandblasting process so that the target texture layer has a second roughness.

The second size is smaller than the first size, so that when the surface layer is treated with a second-size sandblasting process, the iron sand of the second size can affect at least a part of the texture of the target texture layer, so that the target texture layer has a second roughness. At least a part of the target texture layer has a second roughness, and the surface layer has a first roughness, which enhances the leather-like visual effect of the housing. Similarly, the second size also characterizes the size of the iron sand used in the sandblasting process.

In some embodiments, when the surface layer of the housing is stamped, the stamping pressure is in the range of 700 T to 900 T, and the stamping temperature is greater than or equal to 300° C. Considering that this stamping pressure and/or stamping temperature may cause deformation issues in the housing, based on this, FIG. 8 of the present disclosure shows a flowchart of another production method provided by the present disclosure, the method includes the following.

At S801, the surface layer of the housing is stamped to form a target texture layer on the housing surface. The target texture layer and the surface layer have different heights in the thickness direction of the housing, the target texture layer is irregular in shape, and the target texture layer presents a leather-like visual effect.

At S802, the housing with the formed target texture layer is placed on a shaping mold.

At S803, the shaping mold is heated until the temperature of the shaping mold reaches the shaping temperature range, and this temperature is maintained for a first duration to correct the deformation of the housing during the stamping of the surface layer.

At S804, the surface layer is treated with a first-size sandblasting process to achieve a first roughness on the surface layer.

In one embodiment, after stamping the surface layer of the housing and before the sandblasting process of the first size, the housing with the target texture layer is placed on the shaping mold. The shaping mold may include a first sub-mold and a second sub-mold, with a space between the first sub-mold and the second sub-mold. This space is used to accommodate the housing. The housing with the target texture layer is placed in this space. Then, the shaping mold is heated using a temperature control system until its temperature reaches the shaping temperature range, and this state of temperature is maintained for a first duration to correct the deformation of the housing during the stamping of the surface layer. In one embodiment, the shaping temperature can be set to in the range of 280° C. to 300° C., and the first duration can be set to 2 hours. This first duration can be subject to some adjustment. For example, the temperature control system heats the shaping mold to 280° C., while the first duration is set to 2 hours and 10 minutes; or the temperature control system heats the shaping mold to 298° C., while the first duration is set to 2 hours, etc. By using a shaping temperature in the range of 280° C. to 300° C. and a forming duration of 2 hours (i.e., the first duration), the deformed housing can be corrected, thereby ensuring the quality of the housing.

After the deformation of the housing during stamping of the surface layer is corrected, a first-size sandblasting process is performed on the surface layer, resulting in the surface layer having a first roughness.

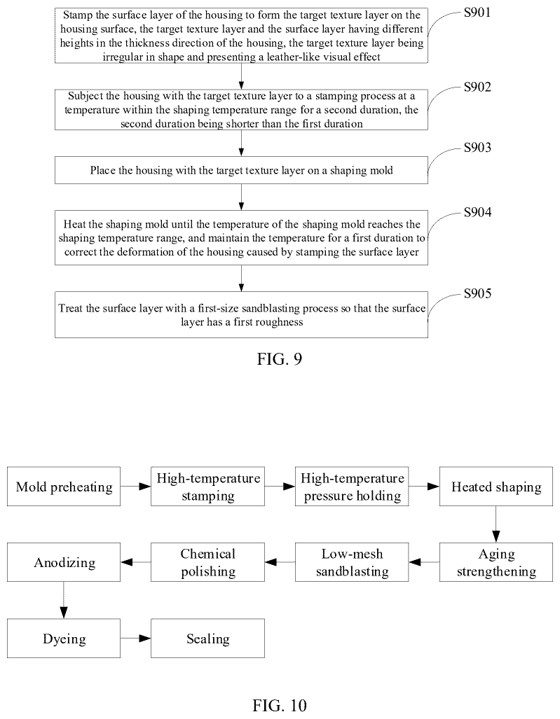

In some embodiments, the housing is placed between a first mold and a second mold, and pressure is applied to a third mold to stamp the surface layer of the housing through the texture layer of the first mold, thereby obtaining the target texture layer. Based on this, a flowchart of another production method shown in FIG. 9 can be used to ensure the target texture layer exhibits a clear texture effect, the method includes the following.

At S901, the surface layer of the housing is stamped to form the target texture layer on the housing surface. The target texture layer and the surface layer have different heights in the thickness direction of the housing, the target texture layer is irregular in shape, and the target texture layer presents a leather-like visual effect.

At S902, the housing with the target texture layer is subjected to a stamping process at a temperature within the shaping temperature range for a second duration, where the second duration is shorter than the first duration.

At S903, the housing with the target texture layer is placed on a shaping mold.

At S904, the shaping mold is heated until the temperature of the shaping mold reaches the shaping temperature range, and the temperature is maintained for a first duration to correct the deformation of the housing caused by stamping the surface layer.

At S905, the surface layer is treated with a first-size sandblasting process to achieve a first surface roughness on the surface layer.

In some embodiments, after the surface layer of the housing is stamped, and before the housing with the target texture layer is placed onto the shaping mold, the housing with the target texture layer can be maintained under stamping. That is, the stamping pressure and stamping temperature are maintained during stamping, the stamping temperature being within the shaping temperature range and being maintained for a second duration. This second duration is shorter than the first duration.

That is, after stamping the surface layer of the housing, the housing is kept between the first mold and the second mold, and the stamping pressure and temperature are maintained for the second duration, so that the texture of the target texture layer has a clear visual effect. This ensures that when the user views the housing, the texture of the target texture layer is clear and close to the standard of genuine leather, resulting in a more realistic visual effect. In one embodiment, the second duration can be set in the range of 8 s to 12 s. The second duration can be set to 8 s to shorten the overall production time; the second duration can also be set to 12 s to ensure that the texture of the target texture layer is relatively clear; of course, the second duration can also be set to 10 s, etc.

Of course, those skilled in the art should know that the production method also includes grinding, mold preheating, anodizing, and other production processes. FIG. 10 shows an example process flowchart for producing an electronic device housing. The production process is as follows: mold preheating→high-temperature stamping→high-temperature pressure holding→heated shaping→aging strengthening→low-mesh sandblasting→chemical polishing→anodizing→dyeing→sealing.

In one embodiment, after the aluminum alloy sheet is obtained, aluminum alloy sheet is pressed to deform the aluminum alloy sheet and to obtain the desired shape and size, i.e., to obtain the housing. Furthermore, the surface layer of the housing is polished to obtain a surface layer with a certain roughness. Further, according to the production method provided in the embodiments of the present disclosure, the mold preheating process is performed. In one embodiment, the mold (such as the first mold, second mold, and third mold mentioned above) and the housing are placed at the target position. At the target position, the distance between the textured surface of the first mold and the target surface of the housing is less than or equal to 2 mm to ensure that the first mold can achieve texture layer production while preventing damage to the housing.

Further, a temperature control system preheats the mold and housing to a temperature greater than or equal to 300° C. for a duration greater than or equal to 30 seconds. This mold preheating step ensures uniform heating of the housing, softening it and reducing its yield strength while increasing its elongation, producing it for the subsequent high-temperature stamping. A higher preheating temperature corresponds to a shorter preheating time. For example, a preheating temperature of 300° C. corresponds to a preheating time of 40 seconds, and a preheating temperature of 350° C. corresponds to a preheating time of 33 seconds, as long as the goal of reducing the yield strength and increasing the elongation of the housing can be achieved.

Next, after mold preheating, the housing is subjected to high-temperature stamping using a stamping mold. This involves applying pressure to the third mold to stamp the surface layer of the housing through the texture layer of the first mold. Simultaneously, the temperature control system maintains the stamping temperature at a preset level to obtain the target texture layer. The high-temperature stamping process uses a stamping pressure of in the range of 700 T to 900 T and a stamping temperature greater than or equal to 300° C.

After high-temperature stamping, the housing with the target texture layer undergoes a high-temperature holding pressure treatment. This involves maintaining the stamping pressure and temperature of the high-temperature stamping process for about 8 to 12 s to ensure a clear visual effect of the target texture layer.

Since the stamping pressure and/or temperature may cause deformation of the housing, a high temperature reshaping treatment is required after the high-temperature holding pressure treatment. The housing with the target texture layer is placed on a shaping mold, and the mold is heated until its temperature reaches the shaping temperature range. In one embodiment, the shaping temperature is in the range of 280° C. to 300° C., and the shaping mold temperature is maintained for 2 hours after reaching the shaping temperature range to correct the deformation of the housing during stamping of the surface layer, i.e., to change the deformation of the housing caused by stamping pressure and/or stamping temperature.

Afterwards, the housing is subjected to aging strengthening. For example, the housing is reheated to a certain temperature and maintained for a certain period to strengthen the housing's strength and hardness, thereby improving the housing's quality.

Furthermore, the surface layer of the housing is subjected to low-mesh sandblasting. For example, sandblasting with 100-120 mesh iron sand is used to cause the surface layer to have a roughness of in the range of 1.4 μm to 1.8 μm, thereby simulating the visual effect of genuine leather.

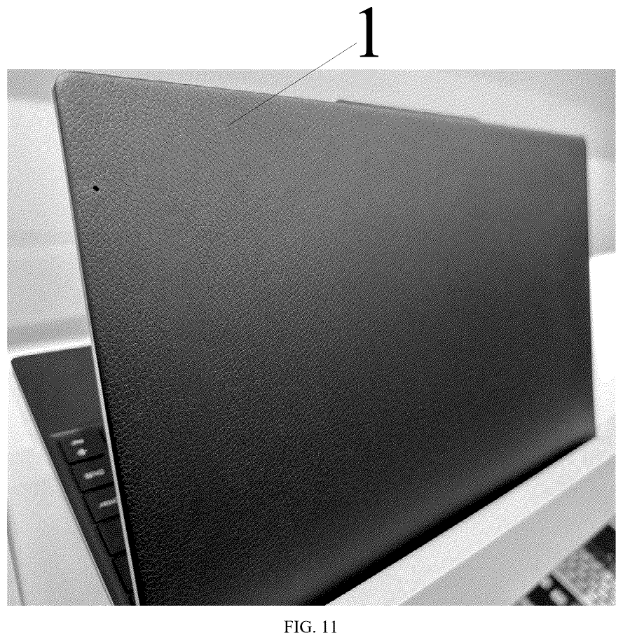

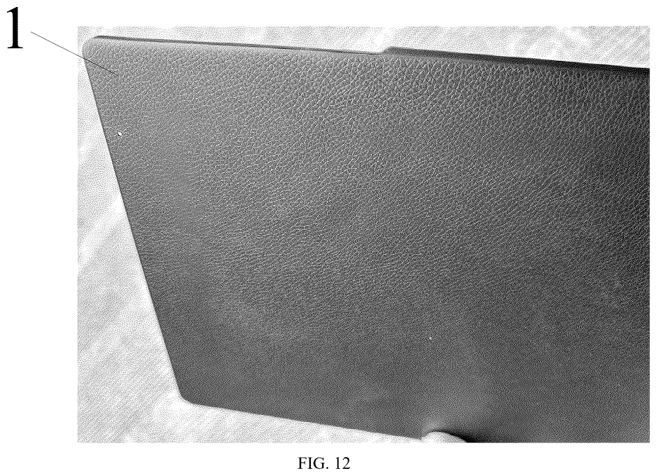

Next, the surface layer and target texture layer of the housing are chemically polished to make them flat and smooth. Then, the surface layer and target texture layer are anodized to improve their hardness and wear resistance, and also to facilitate the filling and adhesion of pigments during subsequent dyeing. Afterwards, the surface layer and target texture layer are dyed. Finally, the surface layer and target texture layer are sealed to obtain a housing with a genuine leather-like visual effect. In one embodiment, FIG. 11 shows one form of the housing provided in the present disclosure, and FIG. 12 shows another form of the housing provided in the present disclosure.

Of course, those skilled in the art should know that the methods in this process flowchart can be adjusted according to actual needs. The production process in FIG. 7 is set for 6063 rolled plates in the T4 state of 6-series materials. For 5-series materials such as 5052 and 5L52, the aging strengthening process can be performed before high-temperature stamping, etc.

In one embodiment, the production method provided in the embodiments of the present disclosure can reduce the yield and elongation of the material during the stamping process. Based on this, 5-series materials such as 5052 and 5L52, as well as 6-series materials such as 6063, can all be applied to the production method of the embodiments of the present disclosure. Furthermore, Table 1 below shows the mechanical properties of 6063 and 5L52 at room temperature, and Table 2 shows the yield strength of 6063 and 5L52 at different temperatures.

TABLE 1
Mechanical Properties

| Material | Heat | Original | surface | Tensile | Yield | | Vickers |
|---|---|---|---|---|---|---|---|
| (Room | treatment | Aluminum | roughness | strength | strength | | hardness |
| temperature) | status | purity | Ra (μm) | (MPa) | (MPa) | Elongation | (HV) |
| 6063 | T4 | 99.75% | / | ≥140 | ≥80 | ≥20% | 40-65 |
| 5L52 | H32 | 99.85% | <0.2 | 205-260 | ≥160 | ≥8% | >55 |

TABLE 2
Yield Strength

| | 200° | 250° | 300° | 350° | 400° | 450° | 500° |
|---|---|---|---|---|---|---|---|
| Material | C. | C. | C. | C. | C. | C. | C. |
| 6063 | 72 | 52 | 39 | 33 | 29 | 20 | 15 |
| 5L52 | | | 80 | 60 | 30 | 25 | 20 |

As shown in Tables 1 and 2, material 6063 exhibits better performance at high temperatures, such as yield strength and elongation.

Furthermore, although exemplary embodiments have been described herein, the scope thereof includes any and all embodiments having equivalent elements, modifications, omissions, combinations (e.g., of the various embodiments across), adaptations or alterations as pertain to the present disclosure. The elements in the claims are to be construed broadly based on the language employed in the claims and are not limited to examples described in the present specification or during the practice of the application, which examples are to be construed as non-exclusive. It is intended, therefore, that the specifications and examples be considered as exemplary only, with a true scope and spirit being indicated by the following claims and their full scope of equivalents.

The above description is intended to be illustrative and not restrictive. For example, the above-described examples (or one or more aspects thereof) may be used in combination with each other. For example, other embodiments may be used by those of ordinary skill in the art upon reading the above description. In addition, in the above detailed description, various features may be grouped together to simplify the application. This is not to be interpreted as an intention that the disclosed features not being claimed are essential to any claim. Rather, inventive subject matter may lie in less than all features of a particular disclosed embodiment. Thus, the following claims are hereby incorporated into detailed description as examples or embodiments, with each claim standing on its own as a separate embodiment, and it is contemplated that these embodiments may be combined with one another in various combinations or permutations. The scope of the invention should be determined with reference to the appended claims, along with the full scope of equivalents to which such claims are entitled.

While various embodiments of the present disclosure have been described in detail, the present disclosure is not limited to these specific embodiments, and various modifications and embodiments can be made by those skilled in the art on the basis of the inventive concept, and these modifications and modifications should be included in the scope of the disclosure.

What is claimed is:

1. An electronic device comprising:
a housing including a target texture layer and a surface layer;
wherein:
in a thickness direction of the housing, a height of the target texture layer is different from a height of the surface layer;
the target texture layer is obtained by stamping the surface layer, the target texture layer is irregular in shape, and the target texture layer presents a leather-like visual effect; and
the surface layer has a roughness achieved by processing the surface layer with a sandblasting process.

2. The electronic device according to claim 1, wherein the target texture layer includes a first part and a second part, a height difference between the first part and the surface layer being different from a height difference between the second part and the surface layer.

3. The electronic device according to claim 1, wherein a width of at least a part of texture of the target texture layer is less than a size of iron sand used in the sandblasting process.

4. The electronic device according to claim 1, wherein:
the roughness is a first roughness and the sandblasting process is a first sandblasting process using iron sand of a first size; and
at least a part of texture of the target texture layer has a second roughness achieved by processing the surface layer with a second sandblasting process using iron sand of a second size, and the second size is smaller than the first size.

5. The electronic device according to claim 1, wherein a texture width of the target texture layer is less than or equal to 170 μm.

6. The electronic device according to claim 1, wherein a height difference between the target texture layer and the surface layer is greater than or equal to 40 μm in the thickness direction of the housing.

7. The electronic device according to claim 1, wherein a surface parameter characterizing the roughness of the surface layer is in a range of 1.4 μm to 1.8 μm.

8. A production method comprising:
stamping a surface layer of a housing to form a target texture layer on the housing, in a thickness direction of the housing, a height of the target texture layer being different from a height of the surface layer, the target texture layer being irregular in shape, and the target texture layer presenting a leather-like visual effect; and
processing the surface layer with a sandblasting process to achieve a roughness on the surface layer.

9. The method according to claim 8, wherein stamping the surface layer of the housing includes:
placing the housing between a first mold and a second mold, a texture layer of the first mold being disposed opposite to the surface layer of the housing, the first mold including a structure for stamping to form the target texture layer, the first mold being nested in a groove of a third mold, a first thickness of the third mold being greater than a second thickness of the first mold, and a first area of the third mold being greater than a second area of the first mold; and
applying pressure to the third mold to stamp the surface layer of the housing through the texture layer of the first mold to obtain the target texture layer.

10. The method according to claim 9, wherein applying pressure to the third mold to obtain the target texture layer includes:
applying pressure to the third mold to stamp the surface layer of the housing to obtain the target texture layer including a first part and a second part, a height difference between the first part and the surface layer being different from a height difference between the second part and the surface layer.

11. The method according to claim 8,
wherein the roughness is a first roughness and the sandblasting process is a first sandblasting process using iron sand of a first size;
the method further comprising:
treating the surface layer with a second sandblasting process using iron sand of a second size to achieve a second roughness on at least a part of texture of the target texture layer, the second size being smaller than the first size.

12. The method according to claim 8, further comprising:
placing the housing formed with the target texture layer on a shaping mold; and
heating the shaping mold to a temperature within a shaping temperature range and maintaining the temperature for a duration to correct deformation of the housing generated during stamping the surface layer.

13. The method according to claim 13,
wherein the duration is a first duration;
the method further comprising:
continuing to stamp the housing having the target texture layer at a temperature within the shaping temperature range for a second duration, the second duration being shorter than the first duration.
